(19) United States
(12) Patent Application Publication
(10) Pub. No.: US 2024/0295021 A1
(43) Pub. Date: Sep. 5, 2024

(54) METHOD AND SYSTEM FOR PRODUCING A METAL STRUCTURE

(71) Applicant: FRAUNHOFER-GESELLSCHAFT ZUR FÖRDERUNG DER ANGEWANDTEN FORSCHUNG E.V., München (DE)

(72) Inventors: Thomas KLOTZBÜCHER, Mainz (DE); Nicolai SCHWARZ, Mainz (DE)

(21) Appl. No.: 18/571,949

(22) PCT Filed: Jun. 21, 2022
(86) PCT No.: PCT/EP2022/066841

§ 371 Date: Dec. 19, 2023

(30) Foreign Application Priority Data
Jun. 21, 2021 (DE) 102021116036.7

(51) Int. Cl. C23C 16/18; C23C 16/44; C23C 16/448; C23C 16/48; C23C 16/52; G02B 1/00

(52) U.S. Cl. CPC C23C 16/18; C23C 16/4418; C23C 16/4485; C23C 16/483; C23C 16/52; G02B 1/005

(57) ABSTRACT

A method for producing a metal structure, including the steps of: providing a representation of the form of the structure; providing a gaseous photosensitive precursor having at least one metal and having at least one ligand with a metal-ligand bond between the at least one metal and the at least one ligand; providing a substrate having a surface, such that the gaseous photosensitive precursor surrounds at least the surface of the substrate; selecting a plurality of volume regions of the gaseous photosensitive precursor on the basis of the representation of the form of the structure; and exposing the plurality of selected volume regions of the gaseous photosensitive precursor to electromagnetic radiation, such that the metal-ligand bond is broken in the plurality of selected volume regions by means of multiphoton absorption and the metal is deposited on the surface of the substrate or on a previously formed volume segment of the structure.

### FIELD OF THE INVENTION

The present invention relates to a method and a system for manufacturing a metallic structure.

### BACKGROUND OF THE INVENTION

Structures for optics, in particular optical metamaterials, comprising very small, free-standing and metallic features, are technologically demanding and cost-intensive to manufacture. Examples of such structures are artificially produced optical media, so-called metamaterials, which comprise a negative refraction and are therefore suitable for forming a “superlens” comprising a resolution below the wavelength of the electromagnetic radiation used.

One of the challenges is that, although the structures to be produced comprise a macroscopic expansion of up to several millimetres, the detailed sizes of the structures are in the nanometre range. It must therefore be possible to manufacture the structures across scales. The structures must also be electrically conductive.

Multi-stage methods are used for manufacturing such structures, for example on the basis of electron beam lithography or direct laser writing of a dielectric structure comprising subsequent coating of the surface of the structure with a metallic film.

### SUMMARY OF THE INVENTION

In contrast, the object of the present invention is to provide a method and a system which makes it possible to manufacture a metallic structure, wherein the method is at least less complex or less expensive than the prior art. In addition, it is an object of the present invention to provide a method which makes it possible to manufacture a free-standing metallic structure.

At least one of the aforementioned objects is solved by a method for manufacturing a metallic structure comprising the steps of: providing a representation of the shape of the structure, providing a gaseous photosensitive precursor comprising at least one metal and at least one ligand having a metal-ligand bond between the at least one metal and the at least one ligand, providing a substrate comprising a surface such that the gaseous photosensitive precursor surrounds at least the surface of the substrate, selecting a plurality of volume sections of the gaseous photosensitive precursor based on the representation of the shape of the structure, and exposing the plurality of selected volume sections of the gaseous photosensitive precursor so that the metal-ligand bond in the plurality of selected volume sections is broken by multiphoton absorption and the metal is deposited on the surface of the substrate or a previously formed volume segment of the structure.

The basic idea of the present invention is to manufacture a metallic structure by direct writing utilising multiphoton absorption processes in a gaseous photosensitive precursor. The decisive factor here is that the photosensitive precursor is gaseous.

The effect of the direct writing comprising electromagnetic radiation into the gaseous precursor according to the invention is, on the one hand, the direct ability to produce metallic three-dimensional geometries on any surface across scales from a few micrometres to several tens of millimetres. This has the advantage that components can be numerically optimised and manufactured for the respective application regardless of production-related limitations and integrated into more complex components such as sensors.

On the other hand, the effect of writing the structure directly is a significant reduction of process steps in the manufacturing of metallic structures. This has the advantage that these structures can be manufactured quickly, cost-effectively and automatically, which enables mass production of such structures.

By direct writing, the skilled person understands a maskless writing of the metallic structure. The selection of the plurality of volume sections of the gaseous photosensitive precursor, which are exposed comprising the electromagnetic radiation, is carried out by positioning, in particular focussing, a beam of electromagnetic radiation into the respective selected volume section based on the representation of the shape of the structure. This representation is not a mask that covers or masks certain areas of the precursor, but rather, for example, a data set that enables the electromagnetic radiation to be positioned.

Since the deposition takes place directly from the gas phase, no residues of elements or compounds need to be removed from the produced structure after deposition.

In an embodiment, the structure is written directly by sequentially exposing at least two selected volume sections of the gaseous precursor located at least one above the other or next to each other. At least two volume sections are scanned in such an embodiment.

In an embodiment, a portion of the volume sections from the plurality of selected volume sections of the gaseous photosensitive precursor is exposed sequentially. The implemented process is then a partial serial process. In an embodiment, all of the selected volume sections from the plurality of selected volume sections of the gaseous photosensitive precursor are exposed sequentially. The implemented process is then a fully serial process.

For a partial serial process, in an embodiment, a plurality of foci is formed that simultaneously expose a plurality of selected volume sections. Here, after exposing a first set of selected volume sections, the foci are moved to the volume sections of a second set of selected volume sections. For a fully serial process, comprising a single focus, it is sufficient to scan and expose all selected volume sections one after the other in an embodiment.

In an embodiment, the selected volume sections are all exposed simultaneously. This is then a completely parallel process. Such a process is implemented in an embodiment by forming an interference pattern of the electromagnetic radiation on the surface of the substrate for exposure, so that areas comprising high intensity are created in which multiphoton absorption occurs in the precursor and other areas comprising lower intensity in which no multiphoton absorption occurs.

The choice of precursor comprising at least one metal and at least one ligand with a metal-ligand bond between the at least one metal and the at least one ligand makes it possible to essentially limit the breaking of the metal-ligand bond upon irradiation with electromagnetic radiation to multiphoton absorption. In this way, the resolution is increased when exposing the volume sections of the gaseous photosensitive precursor. Only where the intensity of the electromagnetic radiation is high enough does multiphoton absorption occur in the precursor with sufficient frequency. The corresponding metallic volume segment of the structure—also known as a volume pixel or voxel for short—that forms in the precursor is spatially much more confined or smaller than the diameter of a beam path or a focus of electromagnetic radiation.

In other words, the gaseous photosensitive precursor is transparent or at least largely transparent at an emission frequency of the electromagnetic radiation. In this respect, the precursor is transparent to the electromagnetic radiation as long as the electromagnetic radiation comprises an intensity that is less than the intensity required for effective multiphoton absorption. In this way, the electromagnetic radiation reaches the location where the next volume segment of the structure is to be written.

In an embodiment of the invention, the emission frequency of the electromagnetic radiation, in particular an emission centre frequency of the pulsed electromagnetic radiation, is selected such that the energy of a single photon is less than the energy required to break the metal-ligand bond. Only two or more photons comprising the emission frequency together provide an energy during multiphoton absorption which is equal to or greater than the binding energy of the metal-ligand bond and break it.

In an embodiment of the invention, the electromagnetic radiation for exposure is selected such that an integer multiple of the emission frequency of the electromagnetic radiation multiplied by Planck's quantum of action is equal to or greater than the energy required to break the metal-ligand bond.

Typical binding energies between atoms of a molecule comprising a metal-ligand bond are in the range of 2 eV to 7 eV. This corresponds to a wavelength range of 620 nm to 177 nm of the irradiated electromagnetic radiation.

If, in an embodiment, the electromagnetic radiation for exposure is selected such that it breaks the metal-ligand bond by two-photon absorption, it comprises a wavelength of 150 nm or more, preferably in a range from 200 nm to 1500 nm and particularly preferred in a range from 300 nm to 1300 nm.

In an embodiment of the invention, the multiphoton absorption is a two-photon absorption.

According to the invention, the breaking of the metal-ligand bond is photosensitive. The photons are absorbed directly by a molecule of the precursor and the bond of the molecule is broken. In contrast, in a pyrolytic method, either the substrate to which a molecule is attached is heated and then the molecule is broken by heat transfer or the molecule is excited resonantly to vibrate, which in turn heats the molecule so that the metal-ligand bond is thermally broken.

Typical energies for exciting molecular vibrations are around 0.1 eV, i.e. the wavelength of the radiation is then in a range of around 12.4 μm. Compared to a pyrolytic method, the photosensitive breaking of the metal-ligand bond enables a higher spatial resolution during structure formation, since heat conduction effects do not play a role.

It is understood that in the method according to the invention, the metal of the gaseous photosensitive precursor is either deposited directly on the surface of the substrate, this applies to the first layer of the structure, or on previously deposited metal of the structure, so that a multilayer structure and thus a three-dimensional, metallic structure is formed.

In an embodiment, the metallic structure is electrically conductive.

In an embodiment, the electromagnetic radiation is focussed into the precursor to expose the plurality of volume sections. In an embodiment, the electromagnetic radiation is focussed such that the focus is located in the respective volume section of the precursor to be exposed.

In an embodiment, the electromagnetic radiation for exposure is generated by a laser and emitted by the laser.

In an embodiment of the invention, the electromagnetic radiation is a short pulse radiation, preferably comprising a pulse length of 100 ns or less, preferably of 30 ns or less, preferably of 1 ns or less and particularly preferably of 500 fs or less. With the aid of short-pulse radiation, a sufficiently high radiation intensity can be achieved in a focal point of the electromagnetic radiation in order to cause multiphoton absorption in the precursor. The minimum pulse length is determined by the laser technology available for generating the electromagnetic radiation. In an embodiment, the pulse duration is at least 40 attoseconds.

A representation of the shape of the structure within the meaning of the present application is any graphical or numerical description of the shape of the structure, in particular a data set describing the shape. For example, the representation is an automatically processable drawing, in particular a CAD drawing, of the structure. Such a representation can be used to select the volume sections of the precursor to be exposed by the electromagnetic radiation and thus the resulting volume segments of the structure formed by the metal deposition.

In order to effect the exposure in the selected volume segment, a beam path of the electromagnetic radiation, in particular a focus of the electromagnetic radiation, is moved relative to the substrate in an embodiment. This can be done, for example, by moving the substrate relative to a stationary beam path of the electromagnetic radiation or by deflecting the beam path of the electromagnetic radiation relative to the stationary substrate or by a combination of both.

A number of materials are suitable as substrates. In an embodiment of the invention, the substrate comprises a material selected from a group consisting of glass, sapphire, a semiconductor material, in particular silicon, a III-V semiconductor or a II-VI semiconductor, a metal, a ceramic and a plastic. In an embodiment, the substrate is selected such that it is non-absorbent at the emission frequency of the electromagnetic radiation. In this way, additional heating of the substrate is largely avoided.

In a further embodiment, the substrate comprises a glass coated with indium tin oxide (ITO). In this way, charging of the metallic structure is effectively prevented when analysing the produced metallic structure with an electron microscope at a later stage.

The choice of the specific precursor depends on a number of factors. The precursor must be selected in such a way that the bond between the metal and the ligand can be broken using multiphoton absorption of the electromagnetic radiation generated by an available radiation source. The precursor should be stable in the gaseous state in the available system, in particular a process chamber for the precursor. The choice of the various ligands influences properties of the precursor such as photon absorption, vaporisation temperature and aggregate state.

In an embodiment of the invention, the metal is selected from a group consisting of gold, silver, platinum and copper.

In one embodiment of the present invention, the at least one ligand is selected from a group consisting of a carbonyl, a thiocarbonyl, a phosphine, a carboxylate, a hydride, a diketonate, a halide, a polyhaptoalkane, a polyhaptoalkene an alkylsilane, an arylsilane, an alkylamine, an arylamine, a phophonate, an alcohol, an alditol, a ketone, a ketene, a thiol, a thioether, an alkylsulfide, an arylsulfide, an olefin, an alkyne, a heterocycle, an alkenylsilane and an alkyl.

In an embodiment of the invention, the gaseous photosensitive precursor is an organometallic compound.

In an embodiment of the invention, a first ligand is hexafluoroacetylacetonate (hfac) and a second ligand is vinyltriethylsilane (VTES). Herein, in one variant of such an embodiment, the metal is silver (Ag) such that the precursor is (hfac)Ag(VTES).

(hfac)Ag(VTES) enables multiphoton absorption, in particular two-photon absorption, of electromagnetic radiation comprising an emission wavelength, preferably a centre emission wavelength of 800 nm. (hfac)Ag(VTES) shows no significant singlephoton absorption at a centre emission wavelength of 800 nm. In a wavelength range from about 280 nm to 350 nm, (hfac)Ag(VTES) shows significant absorption. When this energy is applied, the metal-ligand bond is broken. A process comprising two-photon absorption therefore requires exposure to electromagnetic radiation with a wavelength in a range from about 560 nm to 700 nm and a process comprising three-photon absorption with a wavelength in a range from about 840 nm to 1050 nm.

(hfac)Ag(VTES) can be easily handled and evaporated at a relatively low evaporation temperature, in particular in a range from 303 to 323 K.

In an embodiment of the invention, a first ligand is hexafluoroacetylacetone (hfac) and a second ligand is vinyltrimethylsilane (VTMS). Herein, in one variant of such an embodiment, the metal is copper (Cu) such that the precursor is (hfac)Cu(VTMS).

(hfac)Cu(VTMS) enables multiphoton absorption, in particular two-photon absorption, of electromagnetic radiation comprising an emission wavelength, preferably a centre emission wavelength of 800 nm. (hfac)Cu(VTMS) shows no significant single-photon absorption at a centre emission wavelength of 800 nm. The absorption maximum of (hfac)Cu(VTMS) is in the range of 280 nm to 350 nm, so that (hfac)Cu(VTMS) shows significant absorption at about 400 nm.

(hfac)Cu(VTMS) can be easily handled and evaporated at a relatively low evaporator temperature, in particular in a range of 303-323 K.

In an embodiment of the invention, a first ligand is Me3 and a second ligand is PR3, wherein the residue R comprises methyl (Me) or ethyl (Et). Herein, in one variant of such an embodiment, the metal is gold (Au) such that the precursor is (Me3)Au(PR3), wherein (R=Me, Et).

In an embodiment of the invention, a first ligand is Me and a second ligand is PR′3, wherein the residue R′ comprises methyl (Me) or ethyl (Et). Herein, in one variant of such an embodiment, the metal is gold (Au) such that the precursor is (Me)Au(PR′3).

In an embodiment of the invention, the structure is three-dimensional such that the representation describes a three-dimensional shape of the structure. In this context, a three-dimensional shape in the sense of the present application is understood to be a shape which extends of at least two volume segments of metal located one above the other, i.e. at least two layers of deposits of metal produced one above the other and preferably one after the other.

A three-dimensional metallic structure, as it can be written directly by the method according to the invention, differs from a quasi-three-dimensional structure, as it could be written by a mask-based method, in that a structural feature, for example an undercut, a web, a column, a needle-shaped or bridge-shaped structure can be generated on a previously formed surface in any spatial direction.

In an embodiment, the structure comprises, in a first plane parallel to the surface of the substrate, a first extension in a selected direction parallel to the surface of the substrate, wherein the first plane is located at a first distance from the surface of the substrate measured in a direction perpendicular to the surface of the substrate. In addition, the structure comprises a second extension in a second plane parallel to the surface of the substrate in the same selected direction parallel to the surface of the substrate, wherein the second plane is located at a second distance from the surface of the substrate measured in the direction perpendicular to the surface of the substrate and wherein the second distance is larger than the first distance. Here, the second extension is larger than the first extension or smaller than the first extension, or if the second extension is equal to the first extension, the position of the volume sections of the structure in the second plane is offset with respect to the position of the volume elements in the first plane. Such a structure cannot be written by a mask-based method. A structure manufactured based on a masked exposure can be varied in height perpendicular to the surface of the substrate, but the position of the volume sections of the structure or the extent of the structure in a single selected direction parallel to the surface of the substrate cannot be varied between different planes.

In an embodiment of the invention, the structure comprises at least one freestanding section. Such a freestanding section as defined in the present application is understood to be a section of the structure which is spaced apart from the substrate, wherein no deposited metal extends between this section of the structure and the substrate in a direction perpendicular to the surface of the substrate, at least in sections.

In a further embodiment, at least two of the plurality of volume sections of the gaseous photosensitive material are located one above the other in a direction perpendicular to the surface of the substrate.

In this way, the structure is built up layer by layer from a plurality of volume segments of deposited metal located one above the other in a direction perpendicular to the surface of the substrate.

In an embodiment of the invention, the structure comprises a structural feature comprising an extension in any selected spatial direction of 3 μm or less, preferably of 1 μm or less and particularly preferred of 0.5 μm or less.

In a further embodiment of the invention, the structure comprises a maximum extension in any selected spatial direction of more than 1 mm.

In an embodiment, the method for manufacturing a metallic structure is used, wherein the structure is an optical metamaterial, in particular a photonic crystal, a plasmonic crystal or a plasmonic waveguide.

Metallic nanostructures comprising electromagnetic fields offer great potential for novel, sensitive sensors. Plasmonic sensors, such as surface plasmon resonance (SPR)-based analysis, are already established methods for biochemical analysis. Three-dimensional metallic nanostructures produced according to the invention can be expected to significantly increase sensitivity. By depositing from the gas phase, such nanostructures can be easily integrated on pre-processed systems, for example on a wafer. This facilitates coupling to other electro-optical functional structures required for the sensors, such as laser diodes and detectors.

Areas of application for such sensors comprising the method according to the invention are medical diagnostics, mobile patient monitoring, preferably plasmon-based biosensor technology or sensor technology in mobile devices.

Applications in the field of semiconductor assembly and connection technology are also conceivable. For this purpose, a metallic structure produced comprising the method according to the invention can be used to connect various semiconductor components, for example on a chip, via the third dimension.

At least one of the aforementioned objects is also solved by a system for carrying out the method according to the invention, as described above in embodiments thereof.

Therefore, the present application also relates to a system for manufacturing a metallic structure comprising a radiation source, wherein the radiation source is arranged such that the radiation source generates and emits electromagnetic radiation at an emission frequency during operation of the system, and a process chamber comprising a substrate holder, wherein the substrate holder is arranged and located such that a substrate can be accommodated thereon so that a surface of the substrate faces into an interior of the process chamber, a reservoir, wherein the reservoir is filled with a photosensitive precursor, wherein the photosensitive precursor comprises at least one metal and at least one ligand with a metal-ligand bond between the at least one metal and the at least one ligand, the product of the emission frequency multiplied by Planck's constant being less than an energy required to break the metal-ligand bond, an evaporator for evaporating the photosensitive precursor, wherein the evaporator is arranged and located such that the gaseous precursor fills the process chamber during operation of the system, a motion device, wherein the motion device is arranged and located such that, during operation of the system, the motion device causes a relative movement between a beam path of the electromagnetic radiation and the substrate holder, wherein the radiation source, the motion device and the process chamber comprising the substrate holder are arranged and located such that, during operation of the system, the electromagnetic radiation exposes a volume section of the process chamber, and comprising a controller, wherein the controller is connected to the motion device such that the motion device is controllable by the controller, and wherein the controller is arranged such that, during operation of the system, the controller controls the motion device based on a representation of the shape of the structure such that a selected plurality of volume sections of the process chamber are exposed to the electromagnetic radiation so that the metal is depositable on a surface of a substrate receivable in the substrate holder or on a previously formed section of the structure.

Insofar as aspects of the invention are described in the present application with respect to the system for manufacturing a metallic structure, they also apply to the corresponding method as previously described in embodiments thereof and vice versa. Insofar as the method is carried out with the system according to the present invention, this system comprises the necessary means therefor. In particular, embodiments of the system are suitable for carrying out the embodiments of the method described in the present application.

In one embodiment of the invention, the motion device is a deflection unit, for example implemented by a combination of mirrors, which causes a deflection of the beam path of the electromagnetic radiation so that the beam path, in particular a focus in the beam path, can scan or sample the individual selected volume sections of the vacuum chamber and thus the volume sections of the precursor.

In an alternative embodiment, such scanning can be carried out by moving the substrate holder by means of an actuator relative to the fixed beam path of the electromagnetic radiation, preferably in three spatial directions. A combination of beam deflection and an actuator for the substrate holder is also conceivable.

In an embodiment, the system comprises a focussing element, wherein the focussing element is arranged and located such that, during operation of the system, the focussing element focusses the electromagnetic radiation into the selected volume section to be exposed.

In an embodiment, the process chamber has a window which is transparent to the electromagnetic radiation and through which the electromagnetic radiation is irradiated into the process chamber during operation of the system.

In one embodiment, the focussing element forms this window for irradiating the electromagnetic radiation into the process chamber.

In an embodiment, the process chamber comprises a heating means which heats all elements located in the process chamber to a temperature such that no condensation of the precursor on elements in the process chamber occurs. In an embodiment, the evaporator and the heating means are one and the same technical component.

### BRIEF DESCRIPTION OF THE DRAWINGS

Further advantages, features and possible applications of the present invention become apparent from the following description of an embodiment and the associated figures. In the figures, similar elements are designated by the same reference numbers.

FIG. 1 is a schematic representation of an embodiment of a system for manufacturing a metallic structure.

FIG. 2 is a schematic representation of a structure deposited by the system shown in FIG. 1.

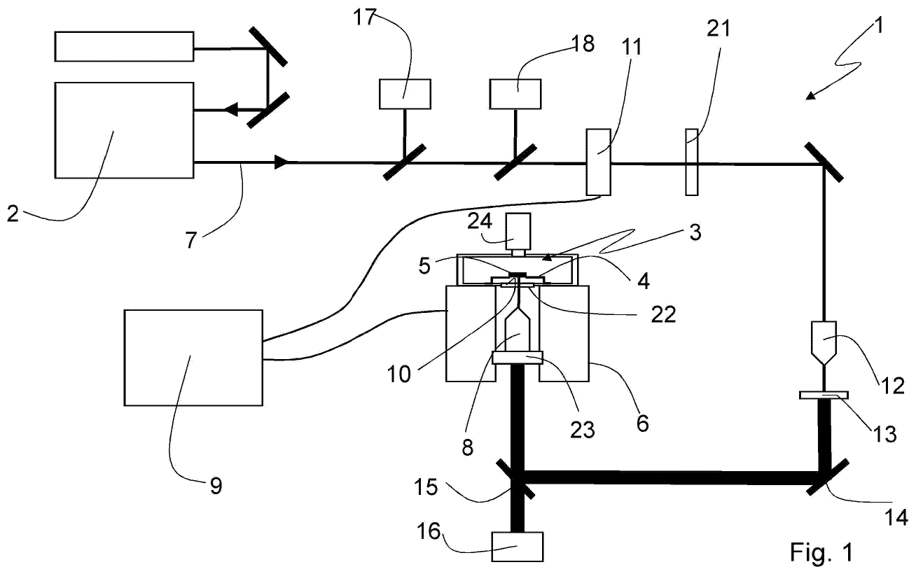

FIG. 1 gives a schematic overview of an embodiment of a system 1 for manufacturing a metallic, three-dimensional and free-standing structure 19 by a method as described below.

### DETAILED DESCRIPTION OF THE INVENTION

The system 1 comprises an optically pumped Ti:sapphire laser 2 as a radiation source for the electromagnetic radiation 7, a process chamber 3 comprising a substrate holder 4, wherein a substrate 5 is accommodated on the substrate holder 4, a three-axis micro-adjuster 6 as a motion device for introducing a relative movement between the beam path of the electromagnetic radiation 7 generated by the laser 2 and the substrate 5, a microscope objective 8 as a focussing element within the meaning of the present application, and a controller 9.

In the embodiment shown, the entire process chamber 3 is on the micro stage, so that it can be moved together with the substrate accommodated therein. The process chamber comprises a window 22 transparent to the electromagnetic radiation 7, through which the electromagnetic radiation 7 is irradiated into the process chamber.

The system 1 further comprises a reservoir in which the precursor is accommodated and an evaporator for evaporating the precursor in the process chamber 3. The reservoir and the evaporator for the precursor are not explicitly shown in FIG. 1. These elements are located such that, during operation of the system 1, the process chamber is filled with the precursor in gaseous form at least in the vicinity of a surface 10 of the substrate 5. The entire process chamber 3 is heated in such a way that the precursor does not condense on the surfaces within the process chamber 3.

The laser 2 is a femtosecond Ti:sapphire laser for generating short optical pulses comprising a central wavelength of 800 nm and a pulse duration of approx. 10 fs. An autocorrelator 17 and a spectrometer 18 are used for beam diagnostics. The dose of the laser beam 7 on the substrate 5 is controlled via a shutter 11, which has an aperture of 1 mm, a very short delay time of 0.54 ms and a minimum exposure time of 0.93 ms. A continuous grey filter wheel 21 (optical density from 0.04 to 3.0) is used for variable beam attenuation. The beam is expanded to a diameter of 6 mm by a beam expansion unit consisting of a microscope objective 12 (20×, NA 0.4, f=5.85 mm) and a collimator lens 13 (f=20 mm).

The laser beam 7 is coupled into the process chamber 3 via a mirror 14 and the beam splitter 15 and an inverted microscope objective 8 (40×, NA 0.65) as a focussing element. By expanding the beam, the wings of the Gaussian beam intensity profile are cut off at the aperture of the objective, which leads to a more homogeneous illumination of the focussing element 8 and thus to an improved aspect ratio of the beam waist. The focal plane of the beam is adjusted along the z-axis to the surface 10 of the substrate 5 or to a surface of an already deposited layer of metal comprising a piezoelectric positioning unit 23, which moves the inverse lens. The focal plane is controlled using a CCD camera 16 located behind the beam splitter 15.

The liquid precursor is evaporated in the specially designed process chamber 3. The process chamber 3 has an inlet for nitrogen purge gas, an outlet to a vacuum pump and a reservoir comprising the precursor. After evacuation of the process chamber 3, the process chamber 3 is heated to a temperature in the range of 303 K to 323 K. The concentration of the then gaseous precursor is measured indirectly using the partial pressure measured by a capacitive pressure sensor 24 mounted on the process chamber 3. The vapour pressure is typically in the mbar range and is set uisng the vapour pressure curve of the precursor. The fs laser beam 7 is coupled into the process chamber 3 through a sapphire glass window and focussed onto the surface 10 of the substrate 5 using a focussing element 8.

In the example described, an organometallic precursor, namely (hfac)Ag(VTES), was used. This is commercially available from the company abcr GmbH. The two ligands that bind to the silver atom are hexafluoroacetylacetone (hfac) and vinyltriethylsilane (VTES).

(hfac)Ag(VTES) shows a number of properties that make it suitable for the method. (hfac)Ag(VTES) is easy to handle and store and can be used directly in the process chamber 4, as the precursor is liquid at room temperature. In addition, the comparatively low evaporation temperature of 303-323 K can be easily and precisely adjusted by an ordinary heater as the evaporator. In order to achieve high spatial resolution by two-photon absorption, it is important that the precursor does not have significant absorption around 800 nm, the emission wavelength of electromagnetic radiation 7, which would essentially prevent two-photon absorption. The absorption maximum of (hfac)Ag(VTES) is in the range of 280-350 nm, so that there is still sufficient absorption at the second harmonic. A glass plate having a thickness of 1 mm and an area of 5×5 mm² is used as the substrate.

In another example, an organometallic precursor, namely (hfac)Cu(VTMS), was used. This is commercially available from the company Gelest. The two ligands that bind to the copper atom are hexafluoroacetylacetone (hfac) and vinyltrimethylsilane (VTMS).

(hfac)Cu(VTMS) shows a number of properties that make it suitable for the method. (hfac)Cu(VTmS) is easy to handle and store and can be used directly in the process chamber 4, as the precursor is liquid at room temperature. In addition, the comparatively low evaporation temperature of 303-323 K can be easily and precisely adjusted by an ordinary heater as evaporator. In order to achieve high spatial resolution by two-photon absorption, it is important that the precursor does not have significant absorption around 800 nm, the emission wavelength of electromagnetic radiation 7, which would essentially prevent two-photon absorption. The absorption maximum of (hfac)Cu(VTMS) is in the range of 280-350 nm, so that there is still sufficient absorption at the second harmonic. A glass plate having a thickness of 1 mm and an area of 5×5 mm² is used as the substrate.

With the system 1 of FIG. 1, any three-dimensional metal structures comprising free-standing individual features can be deposited. To deposite the respective metallic structure 19, the controller 9 has a CAD drawing as a representation of the structure to be deposited. In the embodiment shown, the controller positions the surface 10 of the substrate 5 during the cutting process in such a way that the corresponding volume sections of the vacuum chamber comprising the precursor are sequentially positioned in the focus of the radiation 7 and exposed. In this way, the structure is built up voxel by voxel. In the example considered here, the structure is deposited with a velocity of 0.5 μm/s at an average power of 120 milliwatts.

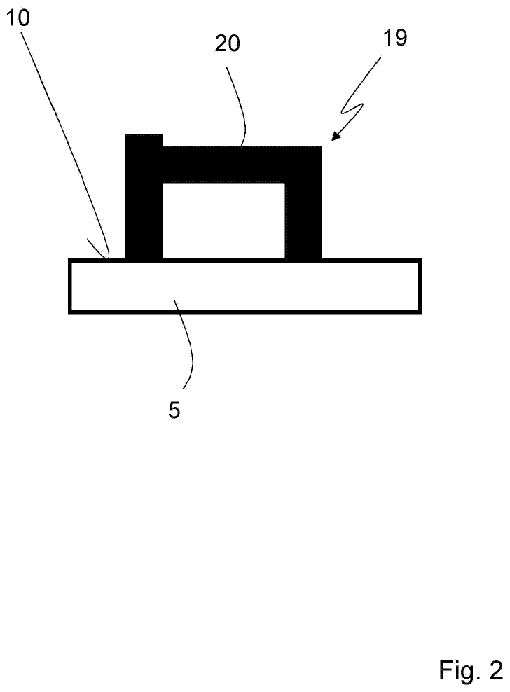

FIG. 2 shows an example of a metallic structure 19 on a glass substrate 5, which was deposited by the system 1 of FIG. 1. The structure 19 forms a self-supporting bridge so that it comprises a free-standing section 20. This free-standing section 20 extends in a direction perpendicular to the surface 10 above the surface 10 of the substrate 5. In some sections, no metal is present between the free-standing section 20 and the surface 10 of the substrate 5. The bridge formed in this way has a cross-section of approximately 800 nm×800 nm in all sections. Such metallic structures can be used as optical metamaterials.

What is claimed is:

1. A method for manufacturing a metallic structure comprising the steps of:
providing a representation of the shape of the structure,
providing a gaseous photosensitive precursor comprising at least one metal and at least one ligand comprising a metal-ligand bond between the at least one metal and the at least one ligand,
providing a substrate comprising a surface such that the gaseous photosensitive precursor surrounds at least the surface of the substrate,
selecting a plurality of volume sections of the gaseous photosensitive precursor based on the representation of the shape of the structure, and exposing the plurality of selected volume sections of the gaseous photosensitive precursor to electromagnetic radiation so that the metal-ligand bond in the plurality of selected volume sections is broken by multiphoton absorption and the metal is deposited on the surface of the substrate or on a previously formed volume segment of the structure.

2. The method according to claim 1, wherein the structure is three-dimensional, so that the representation describes a three-dimensional shape of the structure.

3. The method according to claim 1, wherein the representation of the shape of the structure is a data set describing the shape.

4. The method according to claim 1, wherein the structure comprises a portion spaced from the surface of the substrate in a direction perpendicular to the surface of the substrate, wherein no deposited metal extends at least in portions between the portion of the structure and the substrate.

5. The method according to claim 1, wherein the at least one metal is selected from a group consisting of gold, silver, platinum and copper.

6. The method according to claim 1, wherein the at least one ligand is selected from a group consisting of
a carbonyl,
a thiocarbonyl,
a phosphine,
a carboxylate,
a hydride,
a diketonate,
a halide,
a polyhaptoalkane,
a polyhaptoalkene,
an alkylsilane,
an arylsilane,
an alkylamine,
an arylamine,
a phophonate,
an alcohol,
an alditol,
a ketone,
a ketene
a thiol,
a thioether
an alkyl sulphide,
an aryl sulphide,
an olefin,
an alkyne,
a heterocycle,
an alkenylsilane and
an alkyl.

7. The method according to claim 1, wherein the gaseous photosensitive precursor is an organometallic compound.

8. The method according to claim 1, wherein a first ligand is hexafluoroacetylacetonate and a second ligand is vinyltriethylsilane.

9. The method according to claim 1, wherein a first ligand is hexafluoroacetylacetonate and a second ligand is vinyltrimethylsilane.

10. The method according to claim 1, wherein the electromagnetic radiation is focussed such that a focus of the electromagnetic radiation is in the volume section of the gaseous photosensitive precursor selected for exposure.

11. The method according to claim 1, wherein at least two of the plurality of volume sections of the gaseous photosensitive material are located one above the other in a direction perpendicular to the surface of the substrate.

12. The method according to claim 1, wherein the structure comprises a structural feature comprising an extension in an arbitrarily selected spatial direction of 3 μm or less, preferably of 1 μm or less and particularly preferably of 0.5 μm or less.

13. The method according to claim 1, wherein at least two, preferably all, of the selected volume sections are exposed in succession.

14. The use of a method according to claim 1 for manufacturing a metallic structure, wherein the structure is an optical metamaterial, in particular a photonic crystal, a plasmonic crystal or a plasmonic waveguide.

15. A system for manufacturing a metallic structure comprising:
a radiation source,
wherein the radiation source is arranged such that the radiation source generates and emits electromagnetic radiation comprising an emission frequency during operation of the system, and
a process chamber comprising a substrate holder,
wherein the substrate holder is arranged and located such that a substrate is receivable thereon so that a surface of the substrate faces into an interior of the process chamber,
a reservoir,
wherein the reservoir is filled with a photosensitive precursor, wherein the photosensitive precursor comprises at least one metal and at least one ligand with a metal-ligand bond between the at least one metal and the at least one ligand, wherein the product of the emission frequency multiplied by the Planckian quantum of action is less than an energy required to break the metal-ligand bond,
an evaporator for evaporating the photosensitive precursor,
wherein the evaporator is arranged and located such that the gaseous precursor fills the process chamber during operation of the system,
a motion device,
wherein the motion device is arranged and located in such a way that the motion device causes a relative movement between a beam path of the electromagnetic radiation and the substrate holder during operation of the system,
wherein the radiation source, the motion device and the process chamber comprising the substrate holder are arranged and located in such a way that during operation of the system the electromagnetic radiation exposes a volume section of the process chamber, and
comprising a controller,
wherein the controller is connected to the motion device in such a way that the motion device is controllable by the controller, and
wherein the controller is set up such that, during operation of the system, the controller controls the motion device on the basis of a representation of the shape of the structure such that a selected plurality of volume sections of the process chamber are successively exposed to the electromagnetic radiation, so that the metal is depositable on a surface of a substrate receivable in the substrate holder or on a previously formed section of the structure.

16. The system according to 15, wherein the system comprises a focussing element, wherein the focussing element is arranged and located such that, during operation of the system, the focussing element focusses the electromagnetic radiation into the selected volume section to be exposed.

17. The method according to claim 2, wherein the representation of the shape of the structure is a data set describing the shape,
wherein the structure comprises a portion spaced from the surface of the substrate in a direction perpendicular to the surface of the substrate,
wherein no deposited metal extends at least in portions between the portion of the structure and the substrate, and
wherein the at least one metal is selected from a group consisting of gold, silver, platinum and copper.

18. The method according to claim 17, wherein the at least one ligand is selected from a group consisting of
a carbonyl,
a thiocarbonyl,
a phosphine,
a carboxylate,
a hydride,
a diketonate,
a halide,
a polyhaptoalkane,
a polyhaptoalkene,
an alkylsilane,
an arylsilane,
an alkylamine,
an arylamine,
a phophonate,
an alcohol,
an alditol,
a ketone,
a ketene
a thiol,
a thioether
an alkyl sulphide,
an aryl sulphide,
an olefin,
an alkyne,
a heterocycle,
an alkenylsilane and
an alkyl, and
wherein the gaseous photosensitive precursor is an organometallic compound.

19. The method according to claim 18, wherein a first ligand is hexafluoroacetylacetonate and a second ligand is vinyltriethylsilane,
wherein the electromagnetic radiation is focussed such that a focus of the electromagnetic radiation is in the volume section of the gaseous photosensitive precursor selected for exposure,
wherein at least two of the plurality of volume sections of the gaseous photosensitive material are located one above the other in a direction perpendicular to the surface of the substrate, and
wherein the structure comprises a structural feature comprising an extension in an arbitrarily selected spatial direction of 3 μm or less, preferably of 1 μm or less and particularly preferably of 0.5 μm or less, wherein at least two, preferably all, of the selected volume sections are exposed in succession.

20. The method according to claim 18, wherein a first ligand is hexafluoroacetylacetonate and a second ligand is vinyltrimethylsilane,
wherein the electromagnetic radiation is focussed such that a focus of the electromagnetic radiation is in the volume section of the gaseous photosensitive precursor selected for exposure,
wherein at least two of the plurality of volume sections of the gaseous photosensitive material are located one above the other in a direction perpendicular to the surface of the substrate, and
wherein the structure comprises a structural feature comprising an extension in an arbitrarily selected spatial direction of 3 μm or less, preferably of 1 μm or less and particularly preferably of 0.5 μm or less, wherein at least two, preferably all, of the selected volume sections are exposed in succession.
